(19) United States
(12) Patent Application Publication
(10) Pub. No.: US 2021/0360187 A1
(43) Pub. Date: Nov. 18, 2021

(54) IMAGING ELEMENT, CONTROL METHOD, AND ELECTRONIC DEVICE

(71) Applicant: SONY SEMICONDUCTOR SOLUTIONS CORPORATION, KANAGAWA (JP)

(72) Inventor: MASAKI SAKAKIBARA, KANAGAWA (JP)

(21) Appl. No.: 16/963,779

(22) PCT Filed: May 29, 2019
(86) PCT No.: PCT/JP2019/021197

§ 371 Date: Jul. 21, 2020

(30) Foreign Application Priority Data
Jun. 12, 2018 (JP) 2018-111597

(51) Int. Cl. H04N 5/3745; H04N 5/355; H04N 5/378; H04N 5/369

(52) U.S. Cl. CPC H04N 5/37455; H04N 5/3696; H04N 5/378; H04N 5/355

(57) ABSTRACT

The present disclosure relates to an imaging element, a control method, and an electronic device that are capable of improving noise characteristics at low illuminance levels. A pixel includes a pixel circuit that outputs an analog pixel signal and an analog-to-digital converter circuit that converts the analog pixel signal to a digital pixel signal. The pixel circuit includes a photoelectric conversion section and a charge-to-voltage conversion section. The photoelectric conversion section receives light incident on the pixel, subjects the received light to photoelectric conversion, and generates an electric charge corresponding to a quantity of the light. The charge-to-voltage conversion section is able to select either a reference conversion efficiency used as a reference or a high conversion efficiency higher than the reference conversion efficiency as an efficiency at which the electric charge generated in the photoelectric conversion section is converted to a voltage. The present technology is applicable, for example, to a solid-state imaging apparatus that performs AD conversion in a pixel.

### TECHNICAL FIELD

The present disclosure relates to an imaging element, a control method, and an electronic device, and more particularly to an imaging element, a control method, and an electronic device that are capable of improving noise characteristics at low illuminance levels.

### BACKGROUND ART

In recent years, solid-state imaging elements configured to perform AD (Analog to Digital) conversion have been developed. The solid-state imaging elements include one AD converter for each pixel, and convert analog pixel signals to digital pixel signals in parallel on an individual pixel basis. Further, the solid-state imaging elements may include an AD converter for each group of pixels instead of including an AD converter for each pixel, and adopt a configuration for performing AD conversion on each area where the pixels are disposed.

Moreover, a solid-state imaging apparatus disclosed in PTL 1 is capable of changing the conversion efficiency of an AD converter provided for each pixel or a plurality of pixels, and reducing the conversion efficiency so as to acquire a high-illuminance signal and achieve a wide dynamic range.

### CITATION LIST

### Patent Literature

### [PTL 1]

PCT Patent Publication WO 2017/018215

### SUMMARY

### Technical Problem

However, the solid-state imaging element disclosed in PTL 1 above has not been configured in special consideration of a low-illuminance signal. Therefore, the noise of the AD converter significantly affected noise characteristics at low illuminance levels. Consequently, it has been demanded that the noise characteristics be improved.

The present disclosure has been made in view of the above circumstances, and makes it possible to improve the noise characteristics at low illuminance levels.

### Solution to Problem

An imaging element according to an aspect of the present disclosure includes a pixel including a pixel circuit and an analog-to-digital converter circuit, the pixel circuit outputting an analog pixel signal, the analog-to-digital converter circuit being disposed for the single pixel circuit or disposed in each area where a predetermined number of the pixel circuits are disposed and converting the analog pixel signal to a digital pixel signal, in which the pixel circuit includes a photoelectric conversion section configured to receive light incident on the pixel, subject the received light to photoelectric conversion, and generate an electric charge corresponding to a quantity of the light, and a charge-to-voltage conversion section configured to be able to select either a reference conversion efficiency used as a reference or a high conversion efficiency higher than the reference conversion efficiency as an efficiency at which the electric charge generated in the photoelectric conversion section is converted to a voltage.

A control method according to an aspect of the present disclosure includes, by a control section configured to control in an imaging element, acquiring an analog pixel signal outputted from a pixel including a pixel circuit and an analog-to-digital converter circuit, the pixel circuit outputting the analog pixel signal, the analog-to-digital converter circuit being disposed for the pixel circuit or disposed in each area where a predetermined number of the pixel circuits are disposed and converting the analog pixel signal to a digital pixel signal, and controlling selection of conversion efficiency in a charge-to-voltage conversion section depending on brightness of an image on the basis of the analog pixel signal, the charge-to-voltage conversion section being capable of selecting either a reference conversion efficiency used as a reference or a high conversion efficiency higher than the reference conversion efficiency as an efficiency at which an electric charge generated corresponding to a quantity of light in a photoelectric conversion section is converted to a voltage, the photoelectric conversion section being included in the pixel circuit and adapted to receive light incident on the pixel and subject the received light to photoelectric conversion.

An electronic device according to an aspect of the present disclosure includes an imaging element including a pixel including a pixel circuit and an analog-to-digital converter circuit, the pixel circuit outputting an analog pixel signal, the analog-to-digital converter circuit being disposed for the single pixel circuit or disposed in each area where a predetermined number of the pixel circuits are disposed and converting the analog pixel signal to a digital pixel signal, in which the pixel circuit includes a photoelectric conversion section configured to receive light incident on the pixel, subject the received light to photoelectric conversion, and generate an electric charge corresponding to a quantity of the light, and a charge-to-voltage conversion section configured to be able to select either a reference conversion efficiency used as a reference or a high conversion efficiency higher than the reference conversion efficiency as an efficiency at which the electric charge generated in the photoelectric conversion section is converted to a voltage.

In an aspect of the present disclosure, an analog pixel signal is outputted from the pixel circuit, and converted to a digital pixel signal by the analog-to-digital converter circuit. The analog-to-digital converter circuit is disposed for each pixel circuit or disposed in each area where a predetermined number of pixel circuits are disposed. Further, the photoelectric conversion section receives light incident on the pixel, subjects the received light to photoelectric conversion, and generates an electric charge corresponding to a quantity of the light. The charge-to-voltage conversion section is able to select either a reference conversion efficiency used as a reference or a high conversion efficiency higher than the reference conversion efficiency as an efficiency at which the electric charge generated in the photoelectric conversion section is converted to a voltage. Moreover, a pixel signal outputted from the pixel is acquired, and the selection of conversion efficiency in the charge-to-voltage conversion section is controlled depending on brightness of an image on the basis of the pixel signal.

### Advantageous Effect of Invention

An aspect of the present disclosure makes it possible to improve noise characteristics at low illuminance levels.

It should be noted that the advantages described here are not necessarily restrictive, and any advantages described in this document may be provided by the present disclosure.

### BRIEF DESCRIPTION OF DRAWINGS

FIG. 1 is a block diagram illustrating an example configuration of an embodiment of a solid-state imaging element to which the present technology is applied.

FIG. 2 is a block diagram illustrating an example configuration of a pixel.

FIG. 3 depicts diagrams illustrating first example configurations of a pixel circuit.

FIG. 4 is a diagram illustrating an example configuration of a comparator.

FIG. 5 depicts diagrams illustrating second example configurations of the pixel circuit.

FIG. 6 is a diagram illustrating a third example configuration of the pixel circuit.

FIG. 7 is a flowchart illustrating a conversion efficiency control method.

FIG. 8 depicts diagrams illustrating example histograms to be referenced when conversion efficiency is to be selected.

FIG. 9 is a flowchart illustrating a sensitivity control method.

FIG. 10 is a diagram illustrating an example circuit configuration of a pixel.

FIG. 11 is a diagram illustrating an example circuit configuration of a signal input/output section.

FIG. 12 is a diagram illustrating an example of a drive waveform at a reference conversion efficiency.

FIG. 13 is a diagram illustrating an example of a drive waveform at a low conversion efficiency.

FIG. 14 is a diagram illustrating an example of a drive waveform at a high conversion efficiency.

FIG. 15 is a block diagram illustrating an example configuration of an imaging apparatus.

FIG. 16 is a diagram illustrating example uses of an image sensor.

FIG. 17 is a block diagram depicting an example of schematic configuration of a vehicle control system.

FIG. 18 is a diagram of assistance in explaining an example of installation positions of an outside-vehicle information detecting section and an imaging section.

### DESCRIPTION OF EMBODIMENT

An embodiment to which the present technology is applied will now be described in detail with reference to the accompanying drawings.

### <Example Configuration of Solid-State Imaging Apparatus>

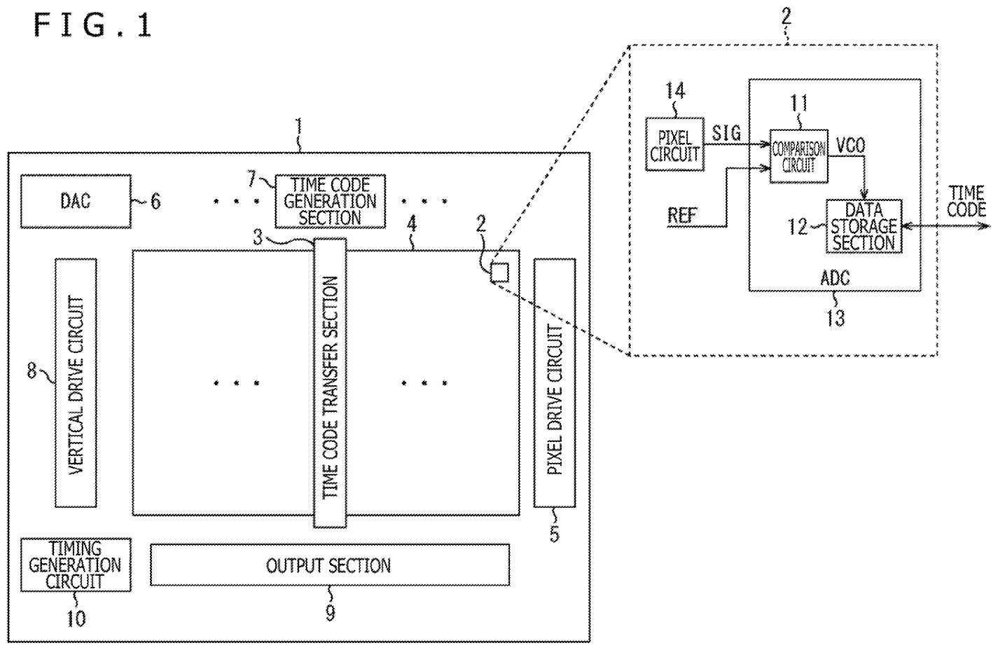

FIG. 1 is a block diagram illustrating an example configuration of an embodiment of a solid-state imaging apparatus to which the present technology is applied.

As depicted in FIG. 1, the solid-state imaging apparatus 1 includes, for example, a pixel array section 4 that is disposed on a semiconductor substrate including silicon (Si) or other semiconductor. The pixel array section 4 includes a plurality of pixels 2 that is disposed in a two-dimensional array. Further, the pixel array section 4 also includes a time code transfer section 3 that transfers a time code generated by a time code generation section 7 to each pixel 2. Moreover, the solid-state imaging apparatus 1 is configured such that the pixel array section 4 is surrounded by a pixel drive circuit 5, a DAC (D/A Converter) 6, the time code generation section 7, a vertical drive circuit 8, an output section 9, and a timing generation circuit 10.

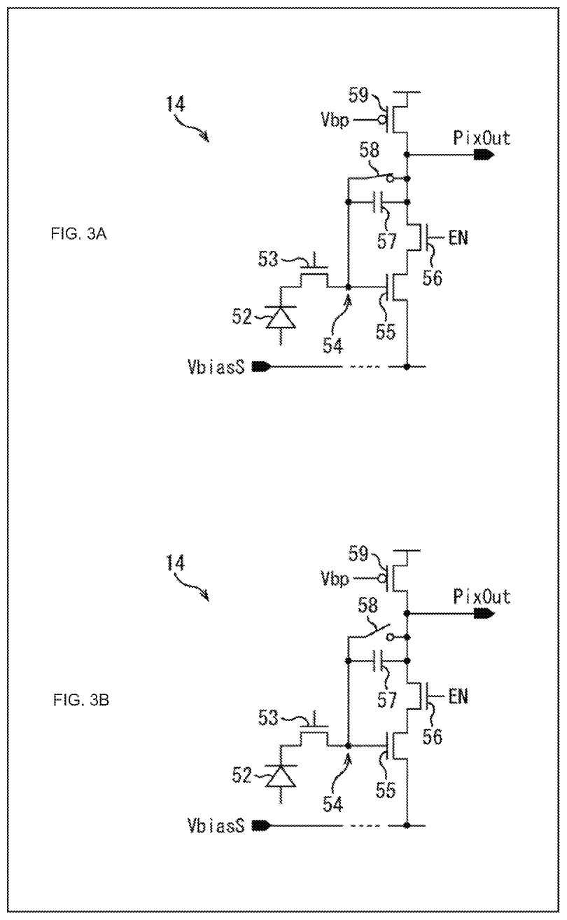

As depicted in the upper right portion of FIG. 1, each of the plurality of pixels 2 disposed in a two-dimensional array includes an ADC 13 and a pixel circuit 14. The ADC 13 includes a comparison circuit 11 and a data storage section 12. The pixel circuit 14 includes a light-receiving element (e.g., a PD 52 in FIG. 3 to be described later). For example, the pixels 2 are each configured such that an electric charge signal corresponding to a light quantity received by the light-receiving element is outputted from the pixel circuit 14, converted by the ADC 13 from an analog pixel signal SIG to a digital pixel signal SIG, and then outputted.

The pixel drive circuit 5 drives the pixel circuit 14 in each pixel 2. The DAC 6 generates a reference signal (reference voltage signal) REF and supplies the generated reference signal REF to each pixel 2. The reference signal REF is a slope signal that monotonically decreases its level (voltage) according to a lapse of time.

The time code generation section 7 generates a time code that is used when each pixel 2 converts (AD converts) an analog pixel signal SIG to a digital signal, and supplies the generated time code to a corresponding time code transfer section 3. A plurality of time code generation sections 7 is disposed for the pixel array section 4. The number of time code transfer sections 3 included in the pixel array section 4 corresponds to the number of time code generation sections 7. In other words, the time code generation sections 7 and the time code transfer sections 3 which transfer the time code generated by the time code generation sections 7 correspond to each other on a one-to-one basis.

The vertical drive circuit 8 performs control such that the digital pixel signals SIG generated in the pixels 2 are outputted to the output section 9 in a predetermined order on the basis of a timing signal supplied from the timing generation circuit 10. The digital pixel signals SIG outputted from the pixels 2 are outputted from the output section 9 to the outside of the solid-state imaging apparatus 1. The output section 9 performs a predetermined digital signal process, such as a black level correction process for correcting the black level or a CDS (Correlated Double Sampling) process as necessary, and then outputs the processed digital pixel signals SIG to the outside.

The timing generation circuit 10 includes, for example, a timing generator for generating various timing signals, and supplies the generated various timing signals to the pixel drive circuit 5, the DAC 6, the vertical drive circuit 8, and the like.

The solid-state imaging apparatus 1 is configured as described above. It should be noted that all circuits included in the solid-state imaging apparatus 1 are formed on a single semiconductor substrate as described with reference to FIG. 1. Alternatively, however, the solid-state imaging apparatus 1 may be configured such that the circuits included in the solid-state imaging apparatus 1 are separately disposed on a plurality of semiconductor substrates.

Operations of the pixels 2 will now be described.

In the pixels 2, an electric charge signal corresponding to a light quantity received by the light-receiving element is outputted, as an analog pixel signal SIG, from the pixel circuit 14 to the ADC 13, AD-converted to a digital pixel signal SIG in the ADC 13, and then outputted.

In the ADC 13, the comparison circuit 11 compares the reference signal REF, which is supplied from the DAC 6, with the pixel signal SIG, and outputs an output signal VCO as a comparison result signal indicative of the result of comparison. For example, when the voltage of the pixel signal SIG coincides with the voltage of the reference signal REF, the comparison circuit 11 inverts the output signal VCO.

The data storage section 12 not only receives the output signal VCO from the comparison circuit 11, but also receives a WR signal, an RD signal, and a WORD signal, which are supplied from the vertical drive circuit 8. The WR signal (hereinafter referred to also as the write control signal WR) indicates a pixel signal write operation. The RD signal (hereinafter referred to also as the read control signal RD) indicates a pixel signal write operation. The WORD signal controls the timing at which the pixels 2 are read during a pixel signal read operation. Further, the data storage section 12 also receives a time code that is generated by the time code generation section 7 and supplied through the time code transfer section 3. It should be noted that, for ease of understanding of the operations of the pixels 2, the control signals are generated by the vertical drive circuit 8 and supplied to the pixel array section 4 according to the description given here. Alternatively, however, a circuit (not depicted) configured to generate the control signals for simultaneously driving all pixels may be disposed, for example, in a horizontal portion. In other words, the circuit for generating the control signals may be disposed anywhere as far as the adopted configuration supplies the control signals to the pixel array section 4.

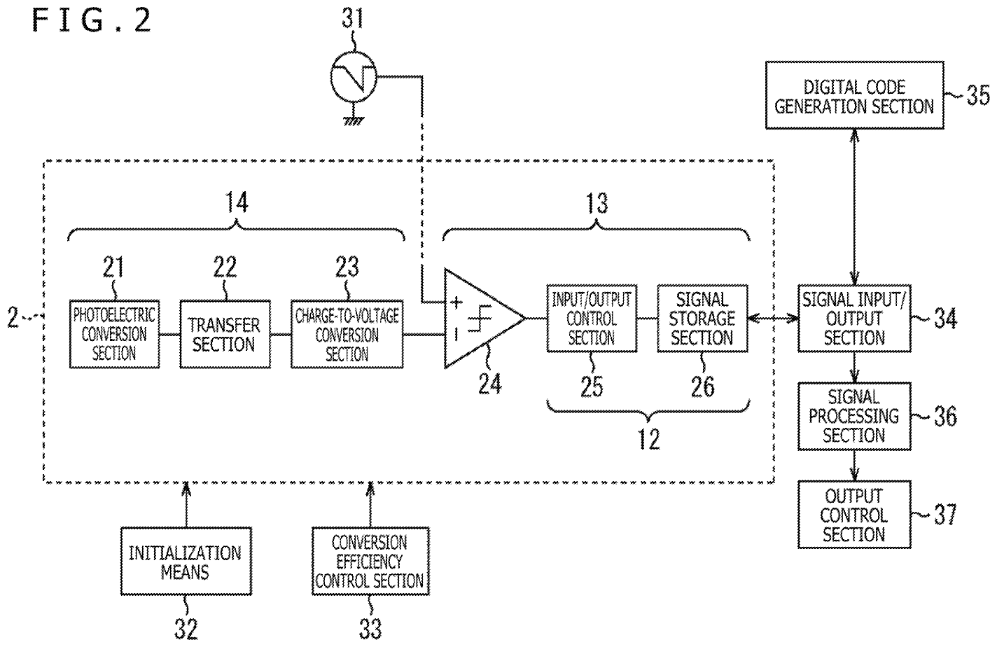

For example, the data storage section 12 includes a latch control circuit (e.g., a later-described input/output control section 25 depicted in FIG. 2) and a latch storage section (e.g., a later-described signal storage section 26 depicted in FIG. 2). The latch control circuit controls a time code write operation and a time code read operation on the basis of the WR signal and the RD signal. The latch storage section stores a time code.

In the time code write operation, the latch control circuit causes the latch storage section to store a time code that is supplied from the time code transfer section 3 while a Hi (High) output signal VCO is inputted from the comparison circuit 11 and updated at unit time intervals. Subsequently, when the voltage of the pixel signal SIG coincides with the voltage of the reference signal REF and the output signal VCO supplied from the comparison circuit 11 is inverted to Lo (Low), the latch control circuit suspends the write (update) of the supplied time code and causes the latch storage section to retain the latest time code stored in the latch storage section. The time code stored in the latch storage section indicates the time at which the pixel signal SIG coincides with the reference signal REF, and represents data indicating that the pixel signal SIG has been a reference voltage at that time, that is, a digitized light quantity value.

After sweep of the reference signal REF is completed and the time code is stored in the latch storage section of each pixel 2 in the pixel array section 4, the operation of each pixel 2 is changed from a write operation to a read operation.

In the time code read operation, the latch control circuit outputs the time code (digital pixel signal SIG) stored in the latch storage section to the time code transfer section 3 at the read timing of each pixel 2 on the basis of the WORD signal for controlling read timing. The time code transfer section 3 sequentially transfers the supplied time codes in the column direction (vertical direction) and supplies them to the output section 9.

In order to make a distinction from the time code to be written in the latch storage section in the time code write operation, digitized pixel data indicating that the pixel signal SIG, which is an inverted time code obtained when the output signal VCO read out from the latch storage section in the time code read operation is inverted, has been a reference voltage at the time, is referred to also as AD-converted pixel data.

### <Example Configuration of Pixel>

FIG. 2 is a block diagram illustrating an example configuration of each pixel 2.

As depicted in FIG. 2, the pixels 2 each include a photoelectric conversion section 21, a transfer section 22, a charge-to-voltage conversion section 23, a comparator 24, an input/output control section 25, and a signal storage section 26. For example, the photoelectric conversion section 21, the transfer section 22, and the charge-to-voltage conversion section 23 are included in the pixel circuit 14 depicted in FIG. 1. Similarly, the comparator 24, the input/output control section 25, and the signal storage section 26 are included in the ADC 13 depicted in FIG. 1. The comparator 24 corresponds to the comparison circuit 11, and the input/output control section 25 and the signal storage section 26 correspond to the data storage section 12.

Further, the pixels 2 are each connected to a reference signal generation section 31 for generating a reference signal REF that is similar to the reference signal REF generated by the DAC 6 depicted in FIG. 1. Moreover, each pixel 2 is further connected to initialization means 32 and a conversion efficiency control section 33. The initialization means 32 initializes (resets) the photoelectric conversion section 21, the charge-to-voltage conversion section 23, and the comparator 24. The conversion efficiency control section 33 controls the selection of conversion efficiency in the charge-to-voltage conversion section 23.

Furthermore, the signal storage section 26 inputs signals to and outputs signals from a signal input/output section 34 that corresponds to the time code transfer section 3 depicted in FIG. 1. A digital time code is supplied to the signal input/output section 34 from a digital code generation section 35 that corresponds to the time code generation section 7 depicted in FIG. 1. Signals outputted from the signal storage section 26 to the signal input/output section 34 are outputted through a signal processing section 36 and an output control section 37 that correspond to the output section 9 depicted in FIG. 1.

It should be noted that, in the example configuration of each pixel 2 depicted in FIG. 2, one ADC 13 is disposed for one pixel circuit 14. However, an alternative configuration may be adopted in which one ADC 13 is disposed, for example, in an area where a predetermined number of pixel circuits 14 are disposed.

### <First Example Configurations of Pixel Circuit>

Circuit configurations of the pixel circuit 14, which are the first example configurations, and the selection of conversion efficiency in the pixel circuit 14 will now be described with reference to FIG. 3.

Depicted in A of FIG. 3 is a circuit configuration of the pixel circuit 14 at a reference conversion efficiency used as the reference. Depicted in B of FIG. 3 is a circuit configuration of the pixel circuit 14 at a high conversion efficiency higher than the reference conversion efficiency.

As depicted in FIG. 3, the pixel circuit 14 includes a PD (Photodiode) 52, a transfer transistor 53, an FD (Floating Diffusion) section 54, an amplifier transistor 55, an enable transistor 56, a capacitor 57, a selector switch 58, and a transistor 59. For example, the PD 52 corresponds to the photoelectric conversion section 21 depicted in FIG. 2, the transfer transistor 53 corresponds to the transfer section 22 depicted in FIG. 2, and the amplifier transistor 55, the enable transistor 56, the capacitor 57, the selector switch 58, and the transistor 59 correspond to the charge-to-voltage conversion section 23 depicted in FIG. 2.

The PD 52 receives light incident on the pixel 2, subjects the light to photoelectric conversion, and generates and stores an electric charge corresponding to a quantity of the light.

The transfer transistor 53 is configured such that its source or drain is connected to the PD 52, and that the remaining one of the source and drain is connected to the FD section 54. In response to a transfer signal TG supplied to the gate electrode of the transfer transistor 53, the transfer transistor 53 transfers the electric charge generated by the PD 52 to the FD section 54.

The FD section 54 is a floating diffusion region that temporarily stores the electric charge transferred through the transfer transistor 53.

The amplifier transistor 55 is configured such that its source or drain is connected to the enable transistor 56, and that the remaining one of the source and drain is connected to a bias voltage. The amplifier transistor 55 generates a voltage corresponding to the electric charge stored in the FD section 54 connected to the gate electrode of the amplifier transistor 55.

The enable transistor 56 is configured such that its source or drain is connected to an output terminal PixOut, and that the remaining one of the source and drain is connected to the amplifier transistor 55. The enable transistor 56 turns on or off in response to an enable signal EN. The enable signal EN controls to enable or disable the amplifier transistor 55.

The capacitor 57 is configured such that one of its terminals is connected to the FD section 54, and that the remaining terminal is connected to the output terminal PixOut. The capacitor 57 forms a feedback capacitor.

The selector switch 58 is disposed in parallel with the capacitor 57. One terminal of the selector switch 58 is connected to the FD section 54, and the other terminal is connected to the output terminal PixOut.

The transistor 59 is configured such that its source or drain is connected to a power supply voltage, and that the remaining one of the source and drain is connected to the output terminal PixOut. A bias voltage Vbp is supplied to the gate terminal of the transistor 59.

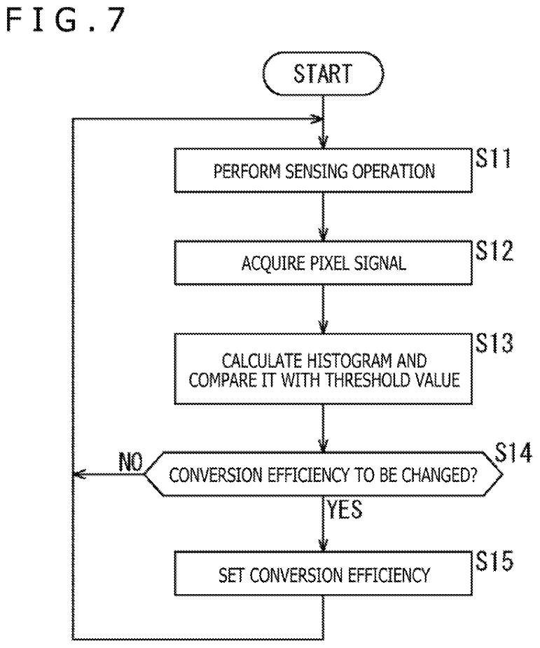

As described with reference to a later-described flowchart of FIG. 7, the pixel circuit 14 configured as described above switches the conversion efficiency between the reference conversion efficiency and the high conversion efficiency by allowing the conversion efficiency control section 33 depicted in FIG. 2 to perform control to turn on or off the selector switch 58.

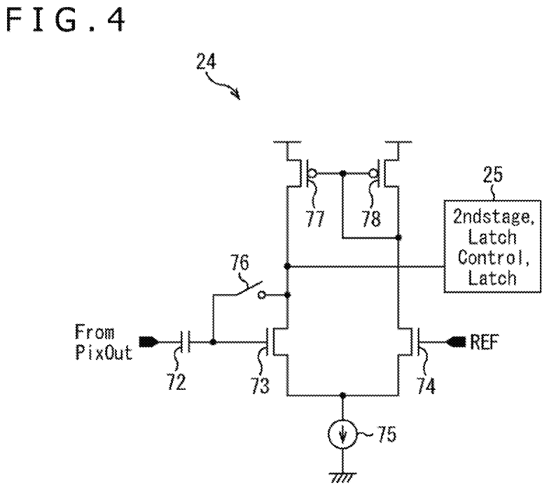

As depicted, for example, in A of FIG. 3, when the reference conversion efficiency is selected, control is made so as to turn on the selector switch 58. Therefore, the pixel circuit 14 is configured as a source-follower readout circuit. As a result, an analog pixel signal obtained by converting an electric charge to a voltage at the reference conversion efficiency is read out from the output terminal PixOut to the comparator 24 disposed in a succeeding stage (see FIG. 4). In other words, after the FD section 54 is initialized in this instance to let the ADC 13 acquire a pixel signal at a reset level, the bias of the transistor (PMOS) 59 also becomes a voltage at which the transistor 59 turns off. During this period, the enable transistor 56 is also vertically connected to be set to a Low voltage so as to disable the amplifier transistor 55 directly connected to the FD section 54.

Meanwhile, as depicted in B of FIG. 3, when the high conversion efficiency is selected, control is made so as to turn off the selector switch 58. Therefore, the pixel circuit 14 is configured as a source-ground readout circuit. As a result, an analog pixel signal obtained by converting an electric charge to a voltage at the high conversion efficiency is read out from the output terminal PixOut to the comparator 24 disposed in a succeeding stage (see FIG. 4). In other words, the transistor (PMOS) 59 is biased in this instance to provide a constant current. The enable transistor 56 is then vertically connected to be set to a High voltage so as to operate the amplifier transistor 55 directly connected to the FD section 54 as a source-ground operational amplifier. It should be noted that a bias voltage VbiasS is determined so as to maintain a proper balance. More specifically, the bias voltage VbiasS is determined to be as high as possible from the viewpoint of pixel signal transfer and as low as possible from the viewpoint of the operating range of the output terminal PixOut in such a way as to be suitably balanced.

It should be noted that a reset in the pixel circuit 14 can be performed by using the selector switch 58. A voltage developed immediately after the selector switch 58 is turned off is read as the reset level. Subsequently, a signal level is transferred from the PD 52 through the transfer transistor 53 to the FD section 54, and then read out.

As described above, the pixel circuit 14 is configured to be able to change the conversion efficiency at which the electric charge generated by the PD 52 is converted to a voltage. For example, the high conversion efficiency can be selected at low illuminance levels in order to improve noise characteristics at the low illuminance levels.

### <Example Configuration of Comparator>

FIG. 4 illustrates an example configuration of the comparator 24, which is disposed in a stage preceding the ADC 13.

As depicted in FIG. 4, the comparator 24 includes a capacitor 72, transistors 73 and 74, a constant current source 75, an auto-zero switch 76, and transistors 77 and 78.

One terminal of the capacitor 72 is connected to the output terminal (PixOut) of the pixel circuit 14, and the other terminal is connected to the gate electrode of the transistor 73. The capacitor 72 cuts off a direct-current component of the analog pixel signal outputted from the pixel circuit 14.

The transistor 73 receives a pixel signal that is outputted from the pixel circuit 14 through the capacitor 72. The transistor 74 receives the reference signal REF from the reference signal generation section 31 depicted in FIG. 2. The transistor 74 forms a differential pair with the amplifier transistor 55 depicted in FIG. 3.

The auto-zero switch 76 is connected between a junction point of the capacitor 72 and the transistor 73 and a junction point of the transistor 73 and the transistor 77, and is used to arrange an operating point. The transistors 77 and 78 form a current mirror. Further, the input/output control section 25 disposed in a stage succeeding the ADC 13 is connected between the transistor 73 and the transistor 77.

In the comparator 24 configured as described above, the capacitor 72 is able to store the offset of an output from the pixel circuit 14 at auto-zero when the capacitor 72 is inserted into an input from the pixel circuit 14. It should be noted that the capacitor 72 and the auto-zero switch 76 are unnecessary as far as the operating point can be arranged by a circuit design of the comparator 24. However, from the viewpoint of possible variation of the operating point, it is preferable that the comparator 24 include the capacitor 72 and the auto-zero switch 76.

### <Second Example Configurations of Pixel Circuit>

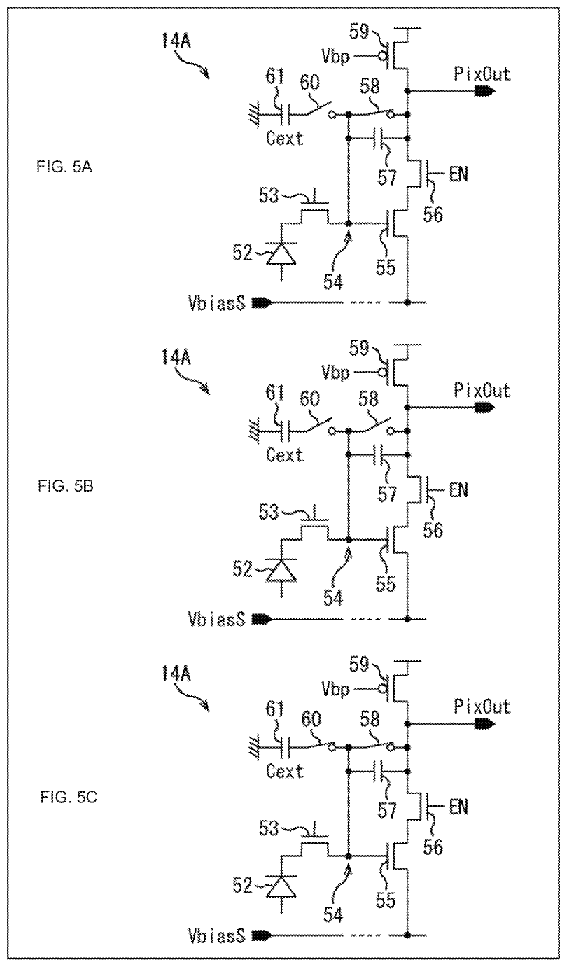

Circuit configurations of a pixel circuit 14A, which are the second example configurations, and the change of conversion efficiency in the pixel circuit 14A will now be described with reference to FIG. 5.

Depicted in A of FIG. 5 is a circuit configuration of the pixel circuit 14A at the reference conversion efficiency. Depicted in B of FIG. 5 is a circuit configuration of the pixel circuit 14A at the high conversion efficiency. Depicted in C of FIG. 5 is a circuit configuration of the pixel circuit 14A at a low conversion efficiency. It should be noted that configurations included in the pixel circuit 14A depicted in FIG. 5 and similar to those in the pixel circuit 14 depicted in FIG. 3 are designated by the same reference signs as the corresponding configurations and will not be redundantly described in detail.

As depicted in FIG. 5, the pixel circuit 14A is similar to the pixel circuit 14 depicted in FIG. 3 in that the former includes the PD 52, the transfer transistor 53, the FD section 54, the amplifier transistor 55, the enable transistor 56, the capacitor 57, the selector switch 58, and the transistor 59.

Additionally, the pixel circuit 14A further includes a selector switch 60 and a capacitor 61.

One terminal of the selector switch 60 is connected to the FD section 54, and the other terminal is connected to the capacitor 61. As is the case with the selector switch 58, the selector switch 60 is turned on and off under the control of the conversion efficiency control section 33 depicted in FIG. 2.

One terminal of the capacitor 61 is connected to the selector switch 60, and the other terminal is grounded.

The pixel circuit 14A, which is configured as described above, is able to select one of three different levels of conversion efficiency among the reference conversion efficiency, the high conversion efficiency, and the low conversion efficiency.

More specifically, when the pixel circuit 14A turns on the selector switch 58 and turns off the selector switch 60 as depicted in A of FIG. 5, the capacitor 61 is disconnected. In other words, the pixel circuit 14A has a circuit configuration similar to the one depicted in A of FIG. 3 and thus selects the reference conversion efficiency.

Meanwhile, when the pixel circuit 14A turns off both the selector switch 58 and the selector switch 60 as depicted in B of FIG. 5, the pixel circuit 14A has a circuit configuration similar to the one depicted in B of FIG. 3 and thus selects the high conversion efficiency.

Further, when the pixel circuit 14A turns on both the selector switch 58 and the selector switch 60 as depicted in C of FIG. 5, the capacitor 61 is connected to select the low conversion efficiency.

As described above, the pixel circuit 14A is able to provide three different levels of conversion efficiency by selecting the connection of the capacitor 61 that lowers the conversion efficiency.

### <Third Example Configuration of Pixel Circuit>

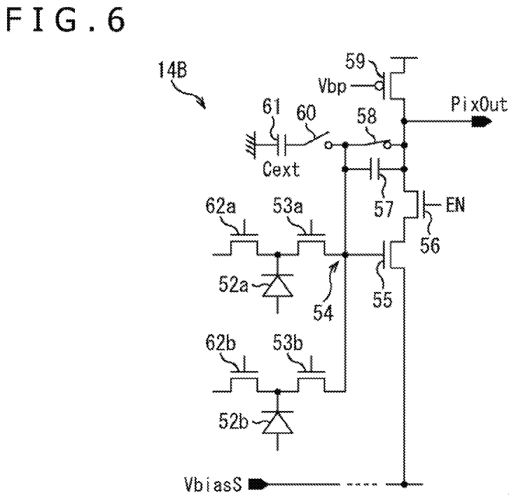

A circuit configuration of a pixel circuit 14B, which is the third example configuration, and the selection of conversion efficiency in the pixel circuit 14B will now be described with reference to FIG. 6. It should be noted that configurations included in the pixel circuit 14B depicted in FIG. 6 and similar to those in the pixel circuit 14 depicted in FIG. 3 and the pixel circuit 14A depicted in FIG. 5 are designated by the same reference signs as the corresponding configurations and will not be redundantly described in detail.

As depicted in FIG. 6, the pixel circuit 14B is similar to the pixel circuit 14 depicted in FIG. 3 in that the former includes the FD section 54, the amplifier transistor 55, the enable transistor 56, the capacitor 57, the selector switch 58, and the transistor 59. Further, the pixel circuit 14B is similar to the pixel circuit 14A depicted in FIG. 5 in that the former includes the selector switch 60 and the capacitor 61.

Additionally, the pixel circuit 14B further includes PDs 52a and 52b, transfer transistors 53a and 53b, and discharge transistors 62a and 62b.

For example, the PD 52a and the PD 52b are formed to exhibit different sensitivities. The PD 52a exhibits a low sensitivity while the PD 52b exhibits a high sensitivity. The PD 52a and the PD 52b can be set to exhibit different sensitivities by making them different from each other, for example, in size indicating a light-receiving area and in light sensitivity (e.g., the difference in the size of an on-chip microlens and the characteristics of detection wavelength (color filters)).

Further, the pixel circuit 14B is able to select one of three different levels of sensitivity by controlling the transfer transistors 53a and 53b and the discharge transistors 62a and 62b so as to selectively use either the PD 52a or the PD 52b for image construction. In other words, the pixel circuit 14B is able to selectively use only the PD 52a having low sensitivity, only the PD 52b having high sensitivity, or both the PD 52a and the PD 52b.

For example, in a case where only the PD 52a is used, the PD 52b continues to be reset by the discharge transistor 62b, which is different from the transfer transistor 53b. Similarly, in a case where only the PD 52b is used, the PD 52a continues to be reset by the discharge transistor 62a, which is different from the transfer transistor 53a. Further, in a case where the PD 52a and the PD 52b are both used, the transfer transistors 53a and 53b are simultaneously driven.

As described above, the pixel circuit 14B is able to provide three different levels of sensitivity by selectively using only the PD 52a having low sensitivity, only the PD 52b having high sensitivity, or both the PD 52a and the PD 52b.

### <Conversion Efficiency Control Method>

A conversion efficiency control method used in the solid-state imaging apparatus 1 will now be described with reference to the flowchart of FIG. 7. FIG. 7 illustrates a process that is performed in the solid-state imaging apparatus 1 having the pixel circuit 14 depicted in FIG. 3.

When, for example, the solid-state imaging apparatus 1 begins to capture an image, the process starts. In step S11, the solid-state imaging apparatus 1 performs a sensing operation with all the pixels 2 disposed in the pixel array section 4. This generates an electric charge corresponding to the quantity of light received by each pixel 2.

In step S12, each pixel 2 converts the electric charge to a voltage at a currently selected conversion efficiency, subjects the voltage to AD conversion to obtain a pixel signal, and outputs the obtained pixel signal. The conversion efficiency control section 33 then acquires the pixel signal.

In step S13, the conversion efficiency control section 33 calculates a histogram of the pixel signal of each pixel 2. Then, the conversion efficiency control section 33 removes defects from the histogram of each pixel signal, and compares the number of pixels having saturated pixel signals with a predetermined threshold value.

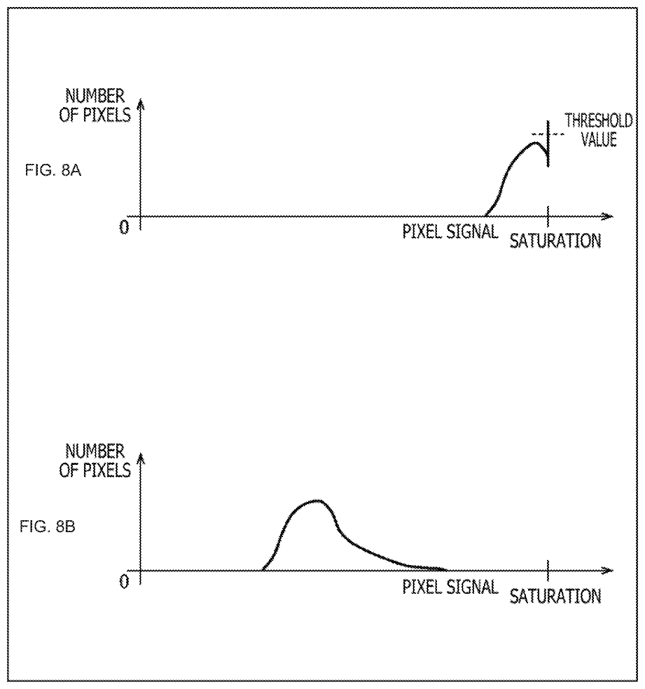

Here, FIG. 8 illustrates example histograms calculated by the conversion efficiency control section 33. A histogram depicted in A of FIG. 8 represents a case where the number of pixels having saturated pixel signals among the pixel signals outputted from all pixels 2 is equal to or greater than the threshold value. In this case, the conversion efficiency control section 33 obtains a comparison result indicating that an image constructed by such pixel signals is excessively bright.

Meanwhile, a histogram depicted in B of FIG. 8 represents a case where the number of pixels having saturated pixel signals among the pixel signals outputted from all pixels 2 is small. In this case, the conversion efficiency control section 33 determines the number of pixels having pixel signals that become saturated when the currently selected conversion efficiency is changed to the high conversion efficiency. Further, also in a case where the levels of pixel signals are low to such an extent that there is no number of pixels having saturated pixel signals even after the conversion efficiency is changed to the high conversion efficiency, the conversion efficiency control section 33 obtains a comparison result indicating that an image constructed by such pixel signals is excessively dark.

In step S14, the conversion efficiency control section 33 determines, according to the comparison result obtained in step S13, whether or not to change the conversion efficiency. For example, in a case where the obtained comparison result indicates that the image is excessively bright or excessively dark, the conversion efficiency control section 33 determines to change the conversion efficiency. Meanwhile, in a case where the obtained comparison result indicates that the image has appropriate brightness (i.e., neither excessively bright nor excessively dark), the conversion efficiency control section 33 determines not to change the conversion efficiency.

In a case where the conversion efficiency control section 33 determines, in step S14, not to change the conversion efficiency, that is, the image has appropriate brightness at the currently selected conversion efficiency, processing returns to step S11. More specifically, the process similar to the above-described one is repeated without changing the currently selected conversion efficiency.

Meanwhile, in a case where the conversion efficiency control section 33 determines, in step S14, to change the conversion efficiency, processing proceeds to step S15.

In step S15, the conversion efficiency control section 33 controls the charge-to-voltage conversion section 23 so as to change the conversion efficiency according to the comparison result obtained in step S13, that is, image brightness based on the pixel signals.

For example, in a case where the number of pixels having saturated pixel signals is equal to or greater than the threshold value as indicated by the histogram depicted in A of FIG. 8, and the comparison result indicates that the image is excessively bright, the conversion efficiency control section 33 controls the charge-to-voltage conversion section 23 so as to lower the conversion efficiency. As a result, as indicated by the histogram depicted in B of FIG. 8, the number of pixels having saturated pixel signals is reduced to almost zero. This enables the solid-state imaging apparatus 1 to acquire an image having appropriate brightness.

Meanwhile, in a case where the comparison result indicates that the levels of pixel signals are low to such an extent that there is no number of pixels having saturated pixel signals even if the conversion efficiency is changed to the high conversion efficiency since the number of pixels having saturated pixel signals is small and the image is excessively dark, the conversion efficiency control section 33 controls the charge-to-voltage conversion section 23 so as to raise the conversion efficiency. In this instance, the conversion efficiency control section 33 is able to cause the charge-to-voltage conversion section 23 to simultaneously select the high conversion efficiency for all pixels 2. When the charge-to-voltage conversion section 23 is set to operate at the high conversion efficiency as described above, the noise characteristics can be improved. This enables the solid-state imaging apparatus 1 to acquire low-noise images even at the low illuminance levels at which images are generally dark.

Upon completion of step S15, processing returns to step S11, and then, the process similar to the above-described one is repeated at the newly selected conversion efficiency.

As described above, the conversion efficiency control section 33 can set the charge-to-voltage conversion section 23 to operate at an appropriate conversion efficiency according to image brightness. Consequently, the solid-state imaging apparatus 1 is able to acquire low-noise images having proper brightness.

It should be noted that the solid-state imaging apparatus 1 having the pixel circuit 14A depicted in FIG. 6 can also control so as to select one of three different levels of conversion efficiency according to determination based on a threshold value in a manner similar to the one described with reference to FIG. 7.

### <Sensitivity Control Method>

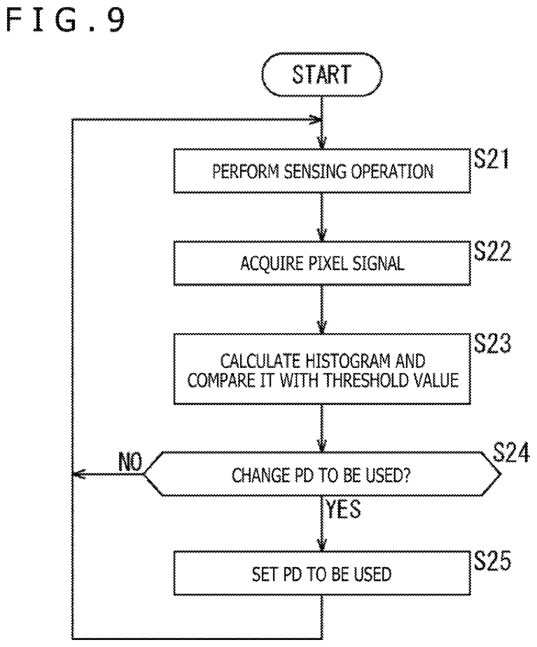

A sensitivity control method used in the solid-state imaging apparatus 1 will now be described with reference to the flowchart of FIG. 9. FIG. 9 depicts a process that is performed by the solid-state imaging apparatus 1 having the pixel circuit 14B depicted in FIG. 6.

In steps S21 to S23, processing is performed in a manner similar to the one described in steps S11 to S13 in FIG. 7. In step S23, a comparison is made by using histograms similar to those depicted in FIG. 8. Then, in step S24, the conversion efficiency control section 33 determines whether or not to change the PD 52 to be used for image construction.

In a case where the conversion efficiency control section 33 determines, in step S24, not to change the PD 52 to be used for image construction, processing returns to step S21. More specifically, in this case, either the PD 52a or the PD 52b, whichever is currently used for image construction, is continuously used to perform a process similar to the one described above.

Meanwhile, in a case where the conversion efficiency control section 33 determines, in step S24, to change the PD 52 to be used for image construction, processing returns to step S25.

In step S25, according to the comparison result obtained in step S13, that is, image brightness based on the pixel signals, the conversion efficiency control section 33 controls so as to change the PD 52 to be used for image construction.

For example, in a case where the number of outputted pixel signals is equal to or larger than a predetermined number, the conversion efficiency control section 33 selects the PD 52a having low sensitivity as is the case with controlling the selector switches 58 and 60 so as to change the conversion efficiency. In a case where the number of outputted pixel signals is within a predetermined range, the conversion efficiency control section 33 selects the PD 52b having high sensitivity. In a case where the smallest number of pixel signals are outputted, the conversion efficiency control section 33 uses both the PD 52a and the PD 52b to make a change so as to acquire the maximum number of pixel signals.

Upon completion of step S25, processing returns to step S21, and then, the process similar to the above-described one is repeated by using the newly selected PD 52.

As described above, the conversion efficiency control section 33 can set an appropriate sensitivity level according to the brightness of an image by changing the PD 52 to be used. Consequently, the solid-state imaging apparatus 1 is able to acquire low-noise images having more proper brightness.

### <Circuit Configuration of Pixels>

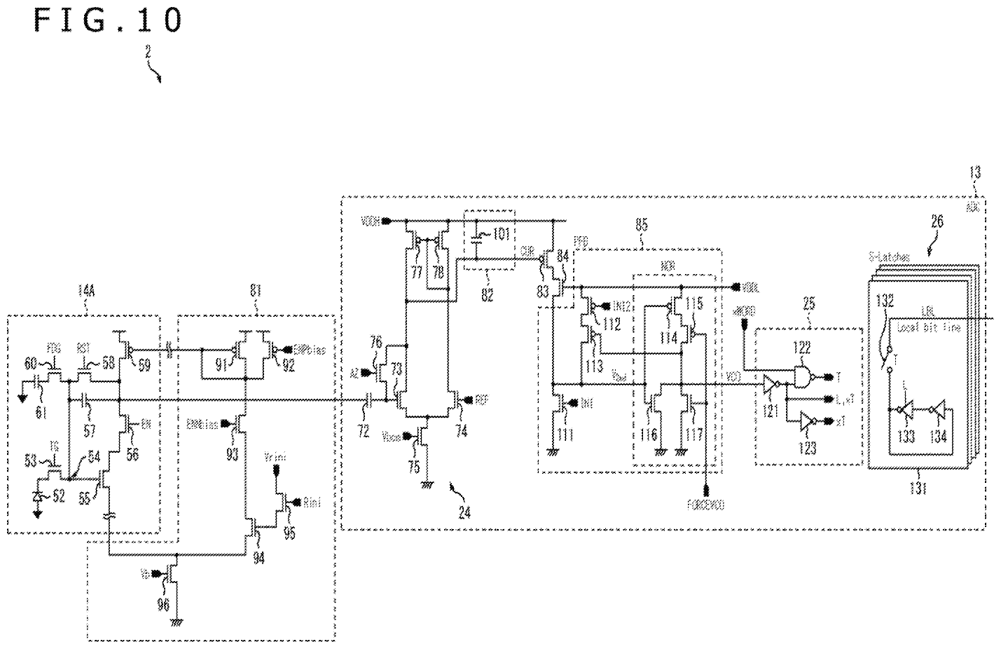

FIG. 10 is a diagram illustrating a detailed example circuit configuration of the pixels 2.

FIG. 10 illustrates an example circuit configuration of the pixels 2 that include the pixel circuit 14A depicted in FIG. 5 and are able to select one of three different levels of conversion efficiency.

As depicted in FIG. 10, the pixels 2 each include a bias circuit 81 that is disposed between the pixel circuit 14A and the ADC 13. The bias circuit 81 includes a combination of transistors 91 to 96.

For example, the bias circuit 81 may be disposed for each pixel circuit 14A. Alternatively, the bias circuit 81 may be shared by four pixel circuits 14A, or four or more pixel circuits 14A may be used for supply purposes. Further, a bias voltage ENPbias supplied to the gate electrode of the transistor 92, the source voltage of the transistor 93, and the drain voltage of the transistor 96 may be made common for all bias circuits 81.

The ADC 13 includes the comparator 24 (see FIG. 4), a bandwidth limiter 82, transistors 83 and 84, a positive feedback circuit (PFB) 85, the input/output control section 25, and the signal storage section 26.

The bandwidth limiter 82 includes a capacitor 101, and bandwidth-limits an output signal outputted from the comparator 24. The output signal outputted from the comparator 24 and bandwidth-limited by the bandwidth limiter 82 is temporarily received by the transistor 83 and then inputted to the positive feedback circuit 85 through the transistor 84, which is series-connected to the transistor 83.

The positive feedback circuit 85 includes a combination of transistors 111 to 117. The transistors 114 to 117 form a NOR circuit. The positive feedback circuit 85 is able to rapidly respond to the output signal outputted from the comparator 24 by feeding an output back to an input.

The input/output control section 25 includes an inverter 121, a NAND circuit 122, and an inverter 123. Further, the signal storage section 26 includes a plurality of 1-bit latches 131. The 1-bit latches 131 each include a switch 132 and inverters 133 and 134.

### <Circuit Configuration of Signal Input/Output Section>

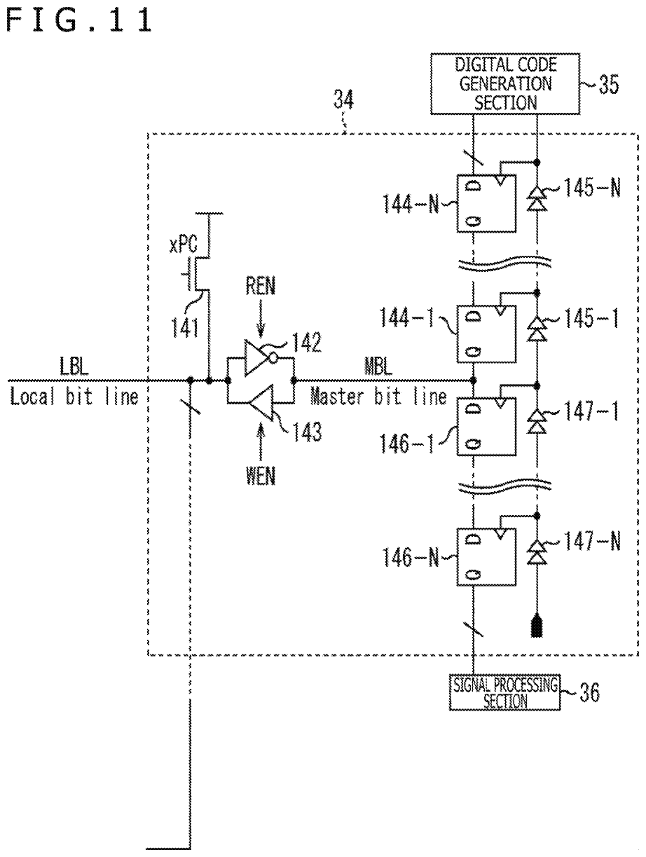

FIG. 11 is a diagram illustrating a detailed example circuit configuration of the signal input/output section 34.

As depicted in FIG. 11, the signal input/output section 34 is configured by connecting a transistor 141, a tristate inverter 142, a tristate buffer 143, FF circuits 144-1 to 144-N, buffer circuits 145-1 to 145-N, FF circuits 146-1 to 146-N, and buffer circuits 147-1 to 147-N. Here, one set of the FF circuits and one set of the buffer circuits are disposed for each latch 131 included in the signal storage section 26. A plurality of such sets is provided as needed for bits necessary for the signal storage section 26.

### <Drive Waveforms>

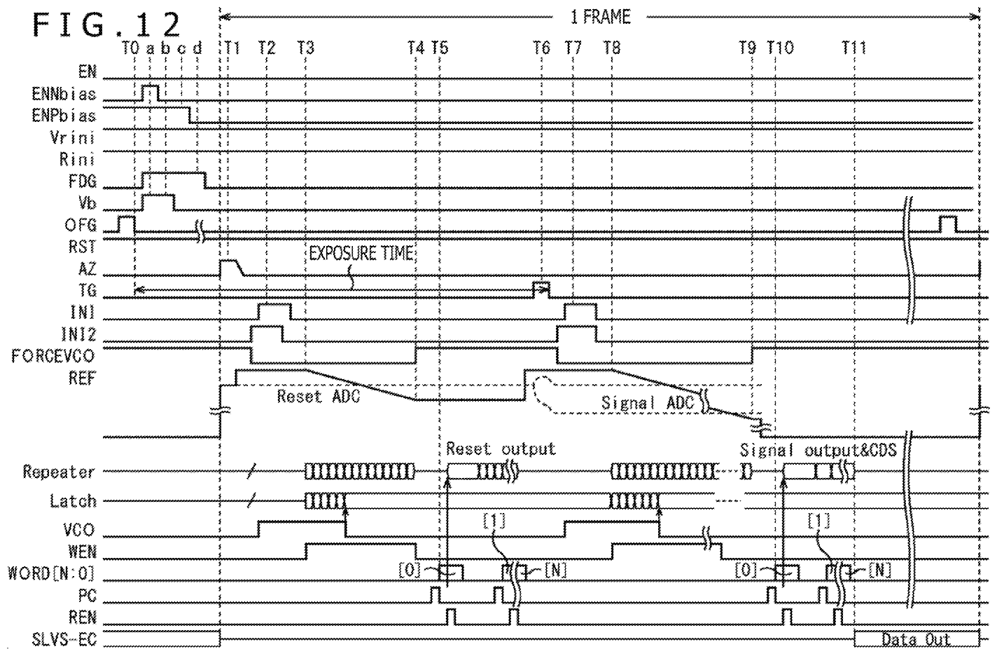

Drive waveforms for controlling the pixels 2 will now be described with reference to FIGS. 12 to 14.

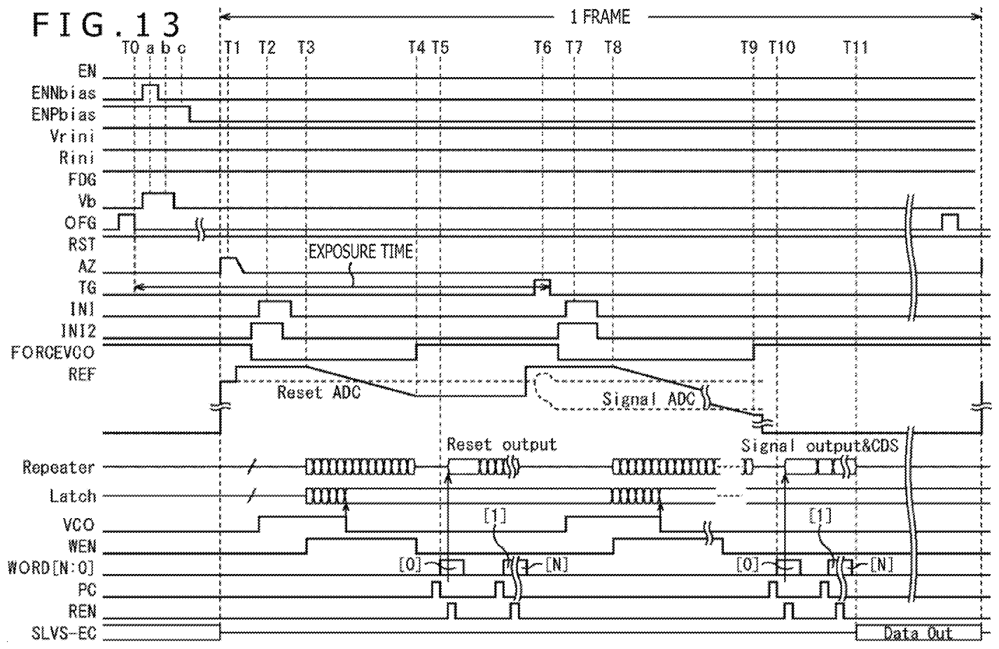

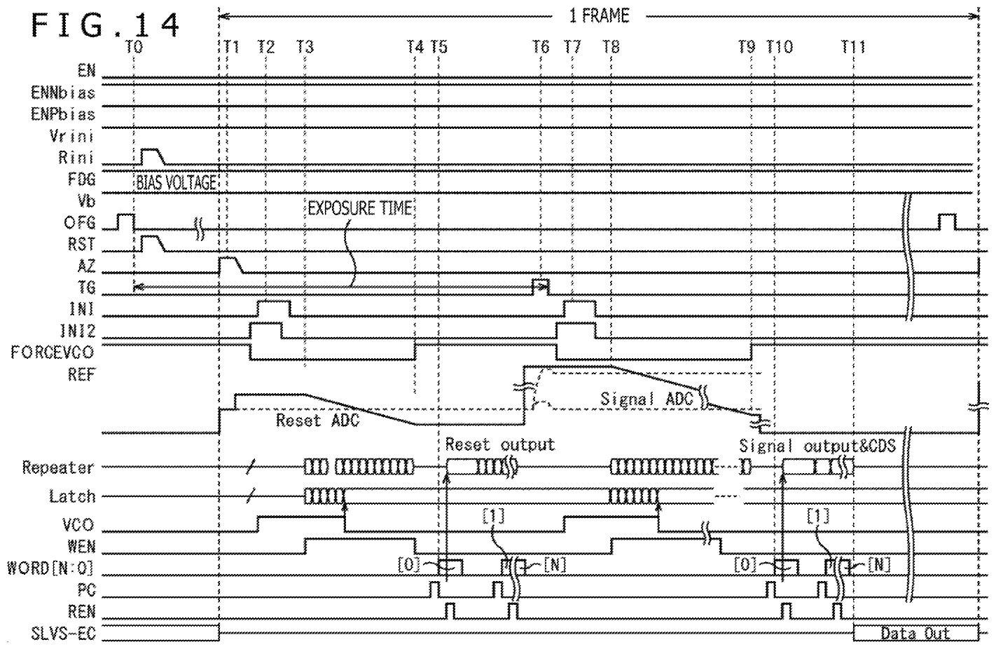

FIG. 12 depicts a drive waveform at the reference conversion efficiency, which is a medium conversion efficiency among three different conversion efficiency levels selectable by the pixel circuit 14A. FIG. 13 depicts a drive waveform at the low conversion efficiency. FIG. 14 depicts a drive waveform at the high conversion efficiency. It should be noted that time points a to d will be described first, and that time points T0 to T11, which are common to FIGS. 12 to 14, will be described later.

As depicted in FIG. 12, when a reset signal RST supplied to the selector switch 58 remains High at time point a in a situation where the reference conversion efficiency is selected, the FD section 54 preceding the transfer transistor 53 is in conduction with a side inputted to the comparator 24. The conversion efficiency is determined by the capacitor 57, which provides a parasitic capacitance of this portion.

Then, for initialization, a bias voltage Vb supplied to the transistor 96 is raised to a constant-current voltage in order to first enable the bias circuit 81, and then the transistor 93 is turned ON (“ENNbias=H” in this case). Further, in order to remove a dark current stored in one frame, conduction of the selector switch 60 is put into the ON state (FDG=H). Then, as the enable transistor 56 is not in conduction, the potential of a portion connected to the transistor (PMOS) 59 is lowered substantially to GND. This initializes the charge-to-voltage conversion section 23. It should be noted that the charge-to-voltage conversion section 23 is put into a floating state when the transistor 93 is put out of conduction after initialization and the transistor 92 is set to an ON-potential (ENPbias=L in this case).

Subsequently, at time point b, the bias voltage Vb supplied to the transistor 96 goes Low such that no current flows. Here, an example control scheme is described. The described example control scheme may be used as is. However, an alternative is to set the bias voltage Vb at the Low level in order to set a differential amplifier at the High potential, and then turn the transistor 93 back ON at time point c.

Finally, at time point d, conduction of the selector switch 60 is put into the OFF state (FDG=L), and then, each of the pixels 2 set at the reference conversion efficiency is subjected to parallel AD conversion.

As depicted in FIG. 13, in a situation where the low conversion efficiency is selected, the control scheme is different from the one depicted in FIG. 12 in that basic initialization similar to the one depicted in FIG. 12 is performed to eventually keep conduction of the selector switch 60 in the ON state (FDG=H) or set the selector switch 60 in the OFF state (FDG=L) for disconnection purposes.

As depicted in FIG. 14, in a situation where the high conversion efficiency is selected, the capacitance Cgs of a source-ground amplifier is used. In other words, when the bias voltage Vb is supplied to the transistor 96, a constant current flows to enable the bias circuit 81.

First of all, at time point a, the reset signal RST supplied to the selector switch 58 and an initialization signal Rini supplied to the transistor 96 are simultaneously driven, and an initialization voltage Vrini for a circuit like a differential circuit is set for the FD section 54 disposed adjacent to the transfer transistor 53. Then, the reset signal RST and the initialization signal Rini are slowly turned OFF. Thus, the amount of charge injection and the amount of clock feed-through can be made equal while the initialization voltage Vrini is present at the operating point.

Here, in a case where control is made at the high conversion efficiency indicated in FIG. 14, the input signal of the ADC 13 disposed in a succeeding stage is such that a reset-level voltage is low while a signal-level voltage is high. In this case, therefore, a low voltage is set for the signal to be inputted to the comparator 24 because the signal does not exercise control to provide a high reset level as indicated in FIGS. 12 and 13. Meanwhile, a high potential is used for signal-level control as is the case with FIGS. 12 and 13. Control in the above-described manner makes it possible to select one of three different levels of conversion efficiency in the single pixel circuit 14A.

Further, a similar effect (acquiring a high-gain signal in a single circuit) can be obtained even when the slope signal monotonically decreases from a low voltage to a high voltage. In such a case, however, a circuit for adjustment is required because the polarity of the output voltage of the comparator 24 is reversed. Therefore, it is preferable that the earlier described method be used.

Time points T0 to T11, which are common to FIGS. 12 to 14, will now be described.

First, at time point T0, exposure control is exercised by initializing the PD 52 with an OFG signal supplied to a discharge transistor (not depicted). Then, an exposure (storage) period is established as an interval between a time point at which the OFG signal changes from ON to OFF and a time point at which the TG signal supplied to the transfer transistor 53 changes from ON to OFF. Further, in a configuration without a discharge transistor, the exposure (storage) period is established as an interval between a time point at which the TG signal changes from ON to OFF in an immediately preceding frame and a time point at which the TG signal subsequently changes from ON to OFF. It should be noted that the OFG signal in FIGS. 12 to 14 is depicted as a pulse having a short ON-period. Alternatively, however, the OFG signal may have a long ON-period or may be inputted as a plurality of pulses having two or more ON-periods. Moreover, from the viewpoint of overflow suppression, for example, an intermediate voltage or an intermediate pulse may be used as the OFG signal instead of a binary signal of ON and OFF values.

At time point T1, the potential of the REF signal supplied to the transistor 74 is set as the initial voltage of the FD section 54 in order to initialize the FD section 54. In this instance, the FD section 54 can be soft reset (subjected to gradual transition from a linear region to a saturated region in order to reduce kT/C noise to approximately half) by raising the potential of the REF signal. Further, as a high-voltage operating range can be set for the FD section 54, it is possible to increase the maximum operating electric charge amount and expand the margin for signal transfer from the PD 52 to the FD section 54. Furthermore, when similar control is made by the RST signal supplied to the selector switch 58 while the FDG signal supplied to the selector switch 60 stays ON, the conversion efficiency can be lowered by the capacitor 57 connected between the selector switch 58 and the selector switch 60. Obviously, the RST signal and the FDG signal are not signals having a fixed voltage and may be controlled at the same time.

At time point T2, a second-stage floating section of the comparator 24 is initialized by an INI signal supplied to the transistor 111 and an INI2 signal supplied to the transistor 112. Here, the INI signal and the INI2 signal are distinguished from each other for explanation purposes. However, they may be identical with each other. In a case where the INI signal and the INI2 signal are identical with each other, their wirings may be merged into a single wiring. This makes it possible to expand the margin for layout design. Further, when a FORCEVCO signal supplied to the transistors 115 and 117 is controlled, the output of the comparator 24 is put into a Ready state, such that a signal can be written into each of the latches 131.

At time point T3, the signal input/output section 34 (repeater) which inputs a time code generated by the time code generation section 7 and outputs AD-converted pixel data that is a time code stored in the signal storage section 26 is controlled, and the time code is written into each of the latches 131 from the outside by a WEN signal supplied to the tristate buffer 143. At the same time, the REF signal which is a monotonically decreasing slope signal is inputted to the transistor 74 and compared with the potential of the FD section 54. At a time point at which the REF signal is inverted, a VCO signal is inverted. Additionally, at this time point, the continuously written time code is stored in each of the latches 131 to stop a write into the corresponding one of latches 131.

The positive feedback circuit 85 is formed, such that the VCO signal operates even when a current of several nanoampere flows in a stage preceding the comparator 24. Therefore, a high PSRR (power supply rejection ratio) can be achieved when the second-stage transistor 83 temporarily receives an output from a stage preceding the comparator 24. Subsequently, when a connection is made to the transistor 84 which is a high-voltage NMOS transistor, control is made, such that the voltage of a succeeding floating section V2nd is not equal to or higher than a gate potential. For the gate potential, the same power supply as for a logic circuit in a succeeding stage can be used. Alternatively, however, a different voltage may be used for the gate potential. Further, for the floating section V2nd, positive feedback is provided by a NOR circuit that is controlled by a test signal, namely, the FORCEVCO signal having a malfunction prevention function. Therefore, rapid transition is achievable. Here, the time codes written into the latches 131 are shifted from each other so as to provide a fixed offset depending on the location because the signal input/output section 34 includes cascade-connected flip-flops as depicted in FIG. 11. However, as described later, the same offset is superimposed on the signal level as well due to CDS computation. Therefore, the offset of time codes written into the latches 131 is canceled.

At time point T4 at which the slope of the REF signal decreases to an appropriate voltage, the AD conversion of the reset levels of all pixels 2 terminates. It should be noted that the comparator 24 left unreversed for some reason is forcibly reversed by the FORCEVCO signal to avoid an influence on a readout process in a succeeding stage. The comparator 24 may be left unreversed because, for example, a circuit failure has occurred or the potential is lowered below the voltage present at the end of a slope due to intense light incident on the PD 52. Then, the constant current of the comparator 24 can be made zero by lowering the voltage of the REF signal to a low potential, such as GND, at the end of AD conversion. Consequently, power consumption can be suppressed until the potential of the REF signal subsequently rises to let a constant current flow to the comparator 24.

At time point T5, the AD-converted pixel data (digital data) stored in each of the latches 131 is read out to the outside. The latches 131 are prepared in a size close to the minimum processable dimensions, for restriction in area, for example. Therefore, the driving force of NMOS is not balanced with that of PMOS. Consequently, the readout capability (time) varies depending on whether the internal signal of each of the latches 131 is High or Low and whether an LBL (Local Bit Line) at the readout destination is High or Low. Further, it is concerned that, when the signals of the latches 131 are read out, they may vary depending on the impedance of the LBL. In order to banish such concern, proper control is made over the transistor 141 under the control of an xPC signal and is made in such a manner that the impedance of the outside of the latches 131 is high as viewed from the latches 131 when latch signals are read out.

Here, the NMOS transistor has a higher transconductance gm than the PMOS transistor. Therefore, the speed of operation is higher when the level of the LBL is lowered from High to Low by the NMOS transistor than when the level of the LBL is raised from Low to High by the PMOS transistor. Consequently, setup is temporarily performed with respect to the power supply before a readout operation is conducted by the xPC signal, and the LBL is preset at the High level each time. Further, regarding a readout from each of the latches 131, there is no difference from the preset value in a case where the read-out signal is at the High level. Therefore, no influence is received even if the capability of the PMOS transistor is low. Thus, the driving force of the PMOS transistor may be low. Meanwhile, in a case where the signal read out from each of the latches 131 is at the Low level, the NMOS transistor plays the role of lowering the potential of the LBL precharged to the High level. However, as a minimum-size transistor is unable to provide sufficient transconductance gm, the gate width W is increased in most cases. However, increasing the gate width W increases an area cost.

Consequently, the impedance of the LBL as viewed from inverters 133 and 134 in each of the latches 131 is increased by making the resistance of the switch 132 disposed at the output of each of the latches 131 higher than at the time of a write operation. More specifically, the switch 132 disposed at the output of each of the latches 131 is controlled so as to turn ON both the NMOS and PMOS transistors included in each of the latches 131 at the time of a write operation and turn ON only the NMOS transistor at the time of a readout operation. This makes it possible to perform a rapid, robust signal readout operation without increasing the size of many NMOS transistors in each of the latches 131. Then, when a REN signal is turned ON, the signal read out to the LBL is read out to the flip-flops with an AD conversion clock set at the Low level. Subsequently, when the AD conversion clock is inputted after the REN signal is turned OFF, the signal read out to the flip-flops is transferred to an output in a bucket-brigade manner. Further, an SRAM (Static Random Access Memory) or other undepicted memory included in the solid-state imaging apparatus 1 is temporarily written into in order to perform CDS.

At time point T6, the voltage of the REF signal is returned to a high level, and the TG signal supplied to the transfer transistor 53 is turned ON so as to transfer the potential of the PD 52 to the FD section 54.

During a period between time point T7 and time point T10, the signal level is AD-converted by performing processing in a manner similar to the one described with respect to time points T2 to T5. Then, at time point T10, the reset level is read out from the SRAM in which the reset level has been temporarily stored at the time of signal level output and is subtracted from the signal level. This makes it possible to cancel (perform a correlated double sampling process on) various types of circuit noise including fixed pattern noise of the comparator 24 and signal input/output section 34 and random noise of the pixels 2 and comparator 24.

At time point T11, a process of transmitting to the outside of the solid-state imaging apparatus 1 is performed through a signal readout circuit, such as an SLVS-EC (Scalable Low Voltage Signaling with Embedded Clock) or other high-speed serial interface. It should be noted that a signal compression or other data band reduction process may be performed prior to the above process.

When the pixels 2 are driven by the above-described control method, it is possible to obtain low-noise output signals and achieve high speed.

It should be noted that the signal storage section 26 may be configured so as to store both a reset level code and a received-light signal level code and output the stored codes to the outside of the solid-state imaging apparatus 1 sequentially or simultaneously through the use of two or more repeaters. Further, the solid-state imaging apparatus 1 including the comparison circuit 11 may adopt a layered structure having two or three layers of semiconductor wafers or more than three layers of semiconductor wafers. Furthermore, in order to provide variable AD conversion resolution, the number of circuit transitions may be decreased to improve power efficiency by keeping the slope of the REF signal constant and controlling so as to refine code transitions by the AD conversion clock at a low illuminance level and gradually coarsen the code transitions as the illuminance level becomes high. Moreover, although not depicted, in a case where the control signals are insufficiently settled in the solid-state imaging apparatus 1 due to an increase in the number of pixels and circuits, circuit changes classified in the category of design activity may be made by improving the drive capability of signals as needed, for example, by buffering.

### <Example Configuration of Electronic Device>

The solid-state imaging apparatus 1 described earlier is applicable to various electronic devices such as a digital still camera, digital video camera, or other imaging system, a mobile phone having an imaging function, and other devices having an imaging function.

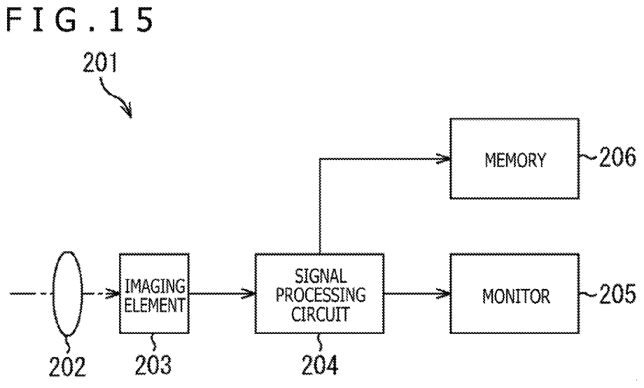

FIG. 15 is a block diagram illustrating an example configuration of an imaging apparatus mounted in an electronic device.

As depicted in FIG. 15, the imaging apparatus 201 includes an optical system 202, an imaging element 203, a signal processing circuit 204, a monitor 205, and a memory 206. The imaging apparatus 201 is able to capture still images and video images.

The optical system 202 includes one or more lenses, guides image light (incident light) from an object to the imaging element 203, and forms an image on the light-receiving surface (sensor section) of the imaging element 203.

The earlier-described solid-state imaging apparatus 1 is applied as the imaging element 203. In accordance with an image formed on the light-receiving surface through the optical system 202, the imaging element 203 stores electrons for a fixed period of time. A signal corresponding to the electrons stored in the imaging element 203 is then supplied to the signal processing circuit 204.

The signal processing circuit 204 performs various signal processes on a pixel signal outputted from the imaging element 203. An image (image data) obtained by allowing the signal processing circuit 204 to perform the signal processes is supplied to and displayed on the monitor 205 or supplied to and stored (recorded) in the memory 206.

When the earlier-described solid-state imaging apparatus 1 is applied to the imaging apparatus 201 configured as described above, the imaging apparatus 201 is able to capture low-noise images, for example, even at low illuminance levels.

### <Example Uses of Image Sensor>

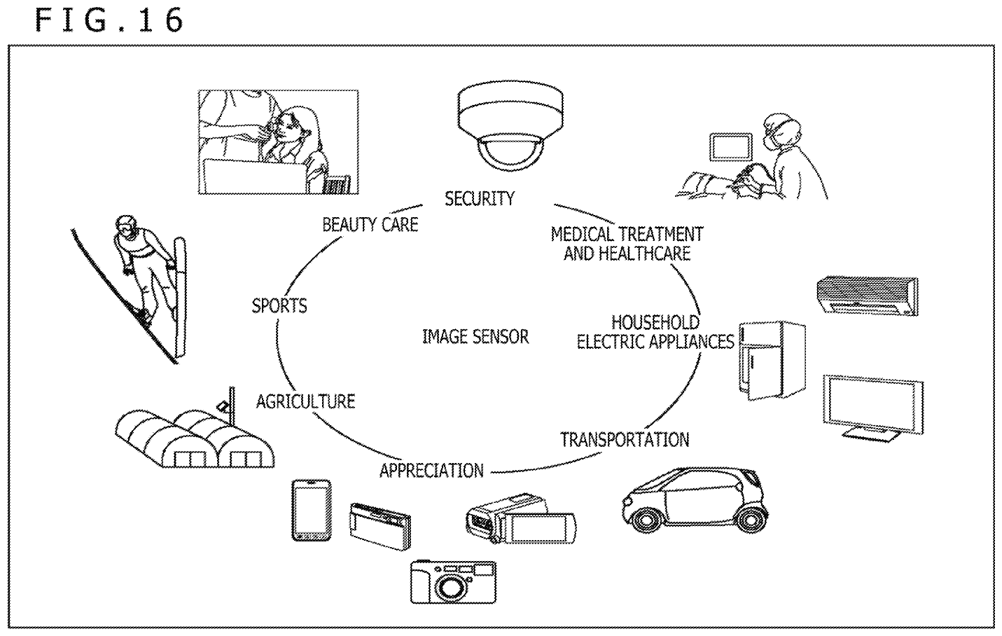

FIG. 16 is a diagram illustrating example uses of the image sensor (solid-state imaging apparatus) described earlier.

The image sensor described earlier can be used in various cases where, for example, visible light, infrared light, ultraviolet light, or X-ray light is to be sensed as described below.
An apparatus used to capture images for appreciation, such as a digital camera or a mobile device with a camera function.
An apparatus used during transportation, for example, to provide an automatic stop feature and other safety driving features and recognize the status of a driver of a vehicle, such as a vehicle-mounted sensor for capturing an image depicting, for instance, a forward or rearward view from the vehicle, a view around the vehicle, or the interior of the vehicle, a surveillance camera for monitoring traveling vehicles and roads, or a distance measurement sensor for measuring, for example, an inter-vehicle distance.
An apparatus used with a TV set, a refrigerator, an air conditioner, or other household electric appliance in order to capture an image of a user's gesture and operate such an electric appliance according to the gesture.
An apparatus used with an endoscope, an angiographic instrument adapted to receive infrared light, or other medical treatment or healthcare instrument.
An apparatus used for security purposes, such as a surveillance camera for crime prevention or a camera for personal authentication.
An apparatus used for beauty care, such as a skin measuring instrument for capturing an image of skin or a microscope for capturing an image of a scalp.
An apparatus used for sports, such as an action camera or a wearable camera for sporting and other events.
An apparatus used for agriculture, such as a camera for monitoring the states of farms and farm products.

### <Example Applications>

The technology according to the present disclosure (the present technology) is applicable to various products. For example, the technology according to the present disclosure may be implemented as an apparatus that is to be mounted in one of various types of mobile bodies such as automobiles, electric automobiles, hybrid electric automobiles, motorcycles, bicycles, personal mobility devices, airplanes, drones, ships, and robots.

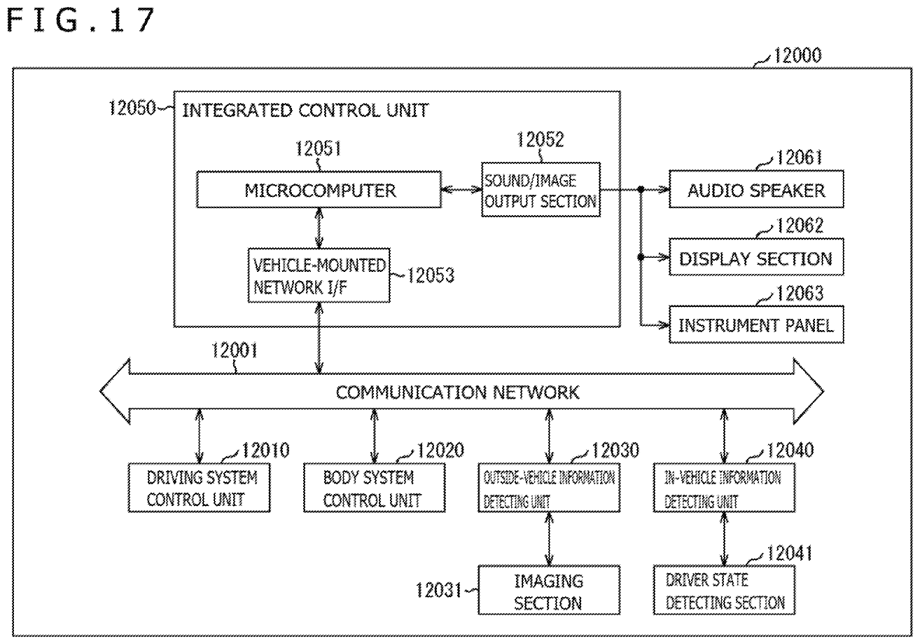

FIG. 17 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 17, the vehicle control system 12000 includes a driving system control unit 12010, a body system control unit 12020, an outside-vehicle information detecting unit 12030, an in-vehicle information detecting unit 12040, and an integrated control unit 12050. In addition, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information regarding the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light quantity of the light. The imaging section 12031 can output the electric signal as an image, or can output the electric signal as information regarding a measured distance. In addition, the light received by the imaging section 12031 may be visible light, or may be invisible light such as infrared rays or the like.

The in-vehicle information detecting unit 12040 detects information regarding the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information regarding the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automatic driving, which makes the vehicle to travel autonomously without depending on the operation of the driver, or the like, by controlling the driving force generating device, the steering mechanism, the braking device, or the like on the basis of the information regarding the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information regarding the outside of the vehicle which information is obtained by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 17, an audio speaker 12061, a display section 12062, and an instrument panel 12063 are illustrated as the output device. The display section 12062 may, for example, include at least one of an on-board display and a head-up display.

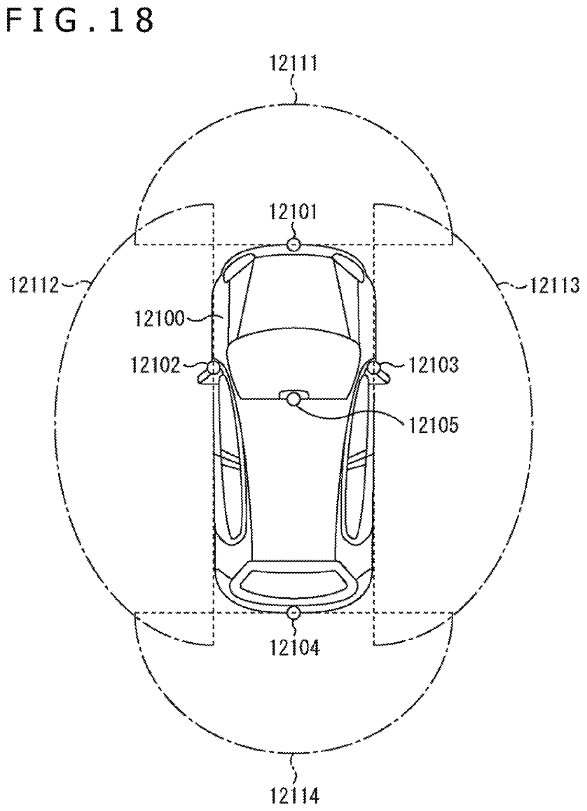

FIG. 18 is a diagram depicting an example of the installation position of the imaging section 12031.

In FIG. 18, the imaging section 12031 includes imaging sections 12101, 12102, 12103, 12104, and 12105.

The imaging sections 12101, 12102, 12103, 12104, and 12105 are, for example, disposed at positions on a front nose, sideview mirrors, a rear bumper, and a back door of the vehicle 12100 as well as a position on an upper portion of a windshield within the interior of the vehicle. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors obtain mainly an image of the sides of the vehicle 12100. The imaging section 12104 provided to the rear bumper or the back door obtains mainly an image of the rear of the vehicle 12100. The imaging section 12105 provided to the upper portion of the windshield within the interior of the vehicle is used mainly to detect a preceding vehicle, a pedestrian, an obstacle, a signal, a traffic sign, a lane, or the like.

Incidentally, FIG. 18 depicts an example of photographing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automatic driving that makes the vehicle travel autonomously without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure is applicable has been described above. The technology according to the present disclosure is applicable, for example, to the imaging section 12031, which is one of the configurations described above. Applying the technology according to the present disclosure, for example, to the imaging section 12031 makes it possible to acquire lower-noise, higher-quality captured images. Therefore, for example, an image recognition process using captured images can be performed with high accuracy.

### <Example Combinations of Configurations>

It should be noted that the present technology may adopt the following configurations.

(1)

An imaging element including:

a pixel including a pixel circuit and an analog-to-digital converter circuit, the pixel circuit outputting an analog pixel signal, the analog-to-digital converter circuit being disposed for the single pixel circuit or disposed in each area where a predetermined number of the pixel circuits are disposed and converting the analog pixel signal to a digital pixel signal,

in which the pixel circuit includes
a photoelectric conversion section configured to receive light incident on the pixel, subject the received light to photoelectric conversion, and generate an electric charge corresponding to a quantity of the light, and
a charge-to-voltage conversion section configured to be able to change either a reference conversion efficiency used as a reference or a high conversion efficiency higher than the reference conversion efficiency as an efficiency at which the electric charge generated in the photoelectric conversion section is converted to a voltage.
   (2)

The imaging element as described in (1) above, further including:

a control section configured to acquire the pixel signal outputted from the pixel, and control the change of the conversion efficiency in the charge-to-voltage conversion section depending on brightness of an image on the basis of the pixel signal.

(3)

The imaging element as described in (2) above, in which, in a case where the image is darker than a predetermined threshold value, the control section changes the photoelectric conversion section to the high conversion efficiency simultaneously for all of a plurality of the pixels.

(4)

The imaging element as described in (2) or (3) above,

in which the charge-to-voltage conversion section includes a selector switch that switches between a source-follower readout circuit configuration for achieving the reference conversion efficiency and a source-ground readout circuit configuration for achieving the high conversion efficiency, and the control section controls the selector switch.

(5)

The imaging element as described in any of (1) to (4) above,

in which the charge-to-voltage conversion section is able to select one of three different levels of conversion efficiency, such as the reference conversion efficiency, the high conversion efficiency, and a low conversion efficiency lower than the reference conversion efficiency.

(6)

The imaging element as described in any of (1) to (5) above,

in which the pixel circuit includes a plurality of the photoelectric conversion sections having different sensitivities.

(7)

The imaging element as described in (6) above further including:

a control section configured to acquire the pixel signal outputted from the analog-to-digital converter circuit, select one of the plurality of the photoelectric conversion sections depending on brightness of an image on the basis of the pixel signal, and use the selected photoelectric conversion section for construction of the image.

(8)

The imaging element as described in (7) above,

in which the pixel circuit includes, as the plurality of the photoelectric conversion sections, a first photoelectric conversion section having a large light-receiving area and a second photoelectric conversion section having a small light-receiving area.

(9)

The imaging element as described in (8) above,

in which the control section selectively uses the first photoelectric conversion section, the second photoelectric conversion section, or both of the first photoelectric conversion section and the second photoelectric conversion section.

(10)

A control method including:

by a control section configured to control in an imaging element,

acquiring an analog pixel signal outputted from a pixel including a pixel circuit and an analog-to-digital converter circuit, the pixel circuit outputting the analog pixel signal, the analog-to-digital converter circuit being disposed for the pixel circuit or disposed in each area where a predetermined number of the pixel circuits are disposed and converting the analog pixel signal to a digital pixel signal; and

controlling change of conversion efficiency in a charge-to-voltage conversion section depending on brightness of an image on the basis of the analog pixel signal, the charge-to-voltage conversion section being capable of changing either a reference conversion efficiency used as a reference or a high conversion efficiency higher than the reference conversion efficiency as an efficiency at which an electric charge generated corresponding to a quantity of light in a photoelectric conversion section is converted to a voltage, the photoelectric conversion section being included in the pixel circuit and adapted to receive light incident on the pixel and subject the received light to photoelectric conversion.

An electronic device including:

an imaging element including
a pixel including a pixel circuit and an analog-to-digital converter circuit, the pixel circuit outputting an analog pixel signal, the analog-to-digital converter circuit being disposed for the single pixel circuit or disposed in each area where a predetermined number of the pixel circuits are disposed and converting the analog pixel signal to a digital pixel signal,
in which the pixel circuit includes
a photoelectric conversion section configured to receive light incident on the pixel, subject the received light to photoelectric conversion, and generate an electric charge corresponding to a quantity of the light, and
a charge-to-voltage conversion section configured to be able to change either a reference conversion efficiency used as a reference or a high conversion efficiency higher than the reference conversion efficiency as an efficiency at which the electric charge generated in the photoelectric conversion section is converted to a voltage.

It should be noted that the embodiment of the present disclosure is not limited to the above-described embodiment and may be variously modified without departing from the spirit and scope of the present disclosure. Further, the advantages described in this specification are merely illustrative and not restrictive. The present disclosure is not limited to such advantages and can provide additional advantages.

### REFERENCE SIGNS LIST

1 Solid-state imaging apparatus, 2 Pixel, 3 Time code transfer section, 4 Pixel array section, 5 Pixel drive circuit, 6 DAC, Time code generation section, 8 Vertical drive circuit, 9 Output section, 10 Timing generation circuit, 11 Comparison circuit, 12 Data storage section, 13 ADC, 14 Pixel circuit, 21 Photoelectric conversion section, 22 Transfer section, 23 Charge-to-voltage conversion section, 24 Comparator, 25 Input/output control section, 26 Signal storage section, 31 Reference signal generation section, 32 Initialization means, 33 Conversion efficiency control section, 34 Signal input/output section, 35 Digital code generation section, 36 Signal processing section, 37 Output control section

1. An imaging element comprising:
a pixel including a pixel circuit and an analog-to-digital converter circuit, the pixel circuit outputting an analog pixel signal, the analog-to-digital converter circuit being disposed for the single pixel circuit or disposed in each area where a predetermined number of the pixel circuits are disposed and converting the analog pixel signal to a digital pixel signal,
wherein the pixel circuit includes
a photoelectric conversion section configured to receive light incident on the pixel, subject the received light to photoelectric conversion, and generate an electric charge corresponding to a quantity of the light, and
a charge-to-voltage conversion section configured to be able to select either a reference conversion efficiency used as a reference or a high conversion efficiency higher than the reference conversion efficiency as an efficiency at which the electric charge generated in the photoelectric conversion section is converted to a voltage.

2. The imaging element according to claim 1, further comprising:
a control section configured to acquire the pixel signal outputted from the pixel, and control the selection of the conversion efficiency in the charge-to-voltage conversion section depending on brightness of an image on a basis of the pixel signal.

3. The imaging element according to claim 2,
wherein, in a case where the image is darker than a predetermined threshold value, the control section changes the photoelectric conversion section to the high conversion efficiency simultaneously for all of a plurality of the pixels.

4. The imaging element according to claim 2,
wherein the charge-to-voltage conversion section includes a selector switch that switches between a source-follower readout circuit configuration for achieving the reference conversion efficiency and a source-ground readout circuit configuration for achieving the high conversion efficiency, and
the control section controls the selector switch.

5. The imaging element according to claim 1,
wherein the charge-to-voltage conversion section is able to select one of three different levels of conversion efficiency, such as the reference conversion efficiency, the high conversion efficiency, and a low conversion efficiency lower than the reference conversion efficiency.

6. The imaging element according to claim 1,
wherein the pixel circuit includes a plurality of the photoelectric conversion sections having different sensitivities.

7. The imaging element according to claim 6, further comprising:
a control section configured to acquire the pixel signal outputted from the analog-to-digital converter circuit, select one of the plurality of the photoelectric conversion sections depending on brightness of an image on a basis of the pixel signal, and use the selected photoelectric conversion section for construction of the image.

8. The imaging element according to claim 7,
wherein the pixel circuit includes, as the plurality of the photoelectric conversion sections, a first photoelectric conversion section having a large light-receiving area and a second photoelectric conversion section having a small light-receiving area.

9. The imaging element according to claim 8,
wherein the control section selectively uses the first photoelectric conversion section, the second photoelectric conversion section, or both of the first photoelectric conversion section and the second photoelectric conversion section.

10. A control method comprising:
by a control section configured to control in an imaging element,
acquiring an analog pixel signal outputted from a pixel including a pixel circuit and an analog-to-digital converter circuit, the pixel circuit outputting the analog pixel signal, the analog-to-digital converter circuit being disposed for the pixel circuit or disposed in each area where a predetermined number of the pixel circuits are disposed and converting the analog pixel signal to a digital pixel signal; and
controlling selection of conversion efficiency in a charge-to-voltage conversion section depending on brightness of an image on a basis of the analog pixel signal, the charge-to-voltage conversion section being capable of selecting either a reference conversion efficiency used as a reference or a high conversion efficiency higher than the reference conversion efficiency as an efficiency at which an electric charge generated corresponding to a quantity of light in a photoelectric conversion section is converted to a voltage, the photoelectric conversion section being included in the pixel circuit and adapted to receive light incident on the pixel and subject the received light to photoelectric conversion.

11. An electronic device comprising:
an imaging element including
a pixel including a pixel circuit and an analog-to-digital converter circuit, the pixel circuit outputting an analog pixel signal, the analog-to-digital converter circuit being disposed for the single pixel circuit or disposed in each area where a predetermined number of the pixel circuits are disposed and converting the analog pixel signal to a digital pixel signal,
wherein the pixel circuit includes
a photoelectric conversion section configured to receive light incident on the pixel, subject the received light to photoelectric conversion, and generate an electric charge corresponding to a quantity of the light, and
a charge-to-voltage conversion section configured to be able to select either a reference conversion efficiency used as a reference or a high conversion efficiency higher than the reference conversion efficiency as an efficiency at which the electric charge generated in the photoelectric conversion section is converted to a voltage.
